(19) United States
(12) Patent Application Publication
(10) Pub. No.: US 2025/0391812 A1
(43) Pub. Date: Dec. 25, 2025

(54) METHODS OF DETERMINING A BONDING STATUS BETWEEN A PORTION OF WIRE AND A WORKPIECE ON A WIRE BONDING SYSTEM

(71) Applicant: Kulicke and Soffa Industries, Inc., Fort Washington, PA (US)

(72) Inventors: Gary S. Gillotti, North Wales, PA (US); Racheli Herskowits, Philadelphia, PA (US); Daniel Muldoon, Hatboro, PA (US); Igor Fokin, Warminster, PA (US)

(73) Assignee: Kulicke and Soffa Industries, Inc., Fort Washington, PA (US)

(21) Appl. No.: 19/243,401

(22) Filed: Jun. 19, 2025

Related U.S. Application Data
(60) Provisional application No. 63/662,444, filed on Jun. 21, 2024.

(51) Int. Cl. H01L 23/00

(52) U.S. Cl. CPC H01L 24/85; H01L 2224/85205; H01L 2224/859

(57) ABSTRACT

A method of determining a bonding status between a portion of wire and a workpiece on a wire bonding system is provided. The method includes the steps of: (a) bringing the portion of wire into contact with a bonding location of a workpiece; (b) commencing a wire bonding process between the portion of wire and the bonding location; and (c) monitoring the bonding status between the portion of wire and the workpiece during the wire bonding process.

### CROSS REFERENCE TO RELATED APPLICATION

This application claims the benefit of U.S. Provisional Application No. 63/662,444, filed on Jun. 21, 2024, the content of which is herein incorporated by reference.

### FIELD

The invention relates to bonding a portion of wire to a workpiece, and more particularly, methods of determining a bonding status between the portion of wire and the workpiece.

### BACKGROUND

In the processing and packaging of semiconductor devices, wire bonding (e.g., ball bonding, wedge bonding, etc.) continues to be a widely used method of providing electrical interconnection between two locations within a package (e.g., between a die pad of a semiconductor die and a lead of a leadframe). More specifically, using a wire bonder (also known as a wire bonding machine) wire loops are formed between respective locations to be electrically interconnected.

An exemplary conventional wire bonding sequence (using ball bonding techniques) includes: (1) forming a free air ball on an end of a wire extending from a bonding tool; (2) forming a first bond on a die pad of a semiconductor die using the free air ball; (3) extending a length of wire in a desired shape between the die pad and a lead of a leadframe; (4) stitch bonding the wire to the lead of the leadframe; and (5) severing the wire. In forming the bonds between (a) the ends of the wire loop and (b) the bond site (e.g., a die pad, a lead, etc.) varying types of bonding energy may be used including, for example, ultrasonic energy, thermosonic energy, thermocompressive energy, amongst others.

Wire structures that are bonded to a workpiece are not limited to wire loops. Examples of other types of wire structures that are bonded to a workpiece include conductive bumps (e.g., stud bumps) and vertical wire structures that are bonded to a single bonding location on a workpiece.

In connection with wire bonding, it is often desirable to confirm that a portion of wire is properly bonded to a bonding location. Wire bonding machines marketed by Kulicke and Soffa Industries, Inc. often utilize a “BITS” process (i.e., Bond Integrity Test System) to confirm that proper wire bonds have been formed. Exemplary details of such processes are disclosed in International Patent Application Publication WO 2009/002345 which is incorporated by reference herein in its entirety. Typically, such a BITS process is enabled after a wire bond is formed (e.g., when the wire bonding tool is raised above the bonded wire portion).

It would be desirable to provide improved methods of determining a bonding status between a portion of wire (e.g., a portion of a wire loop, a conductive bump, etc.) and a workpiece (e.g., a bonding location of a workpiece).

### SUMMARY

According to an exemplary embodiment of the invention, a method of determining a bonding status between a portion of wire and a workpiece is provided. The method includes the steps of: (a) bringing the portion of wire into contact with a bonding location of a workpiece; (b) commencing a wire bonding process between the portion of wire and the bonding location; and (c) monitoring the bonding status between the portion of wire and the workpiece during the wire bonding process.

According to another exemplary embodiment of the invention, a method of determining a clamping status of a clamping system used for clamping a workpiece against a support structure on a wire bonding system is provided. The method includes the steps of: (a) bringing a portion of wire into contact with a bonding location of the workpiece; (b) commencing a wire bonding process between the portion of wire and the bonding location; (c) monitoring a bonding status between the portion of wire and the workpiece during the wire bonding process; and (d) determining the clamping status of the clamping system using the bonding status data monitored in step (c).

According to other embodiments of the invention, the method recited in either of the two immediately preceding paragraphs may have any one or more of the following features: the bonding status is monitored during step (c) by detecting contact between the portion of wire and the bonding location; the bonding status is monitored during step (c) by detecting contact between (i) a wire source including the portion of wire and (ii) the bonding location; the bonding status includes at least one of (i) a bonded wire condition, (ii) a broken wire condition, and (iii) a missing wire condition; the portion of wire is a free air ball configured to be bonded to the bonding location; the portion of wire is configured to be a first wire bond of a wire loop; the portion of wire is configured to be a second wire bond of a wire loop; the portion of wire is configured to be a conductive bump; the portion of wire is configured to be a vertical wire structure bonded to the workpiece at a single location; step of (d) declaring the bonding status of the portion of wire and the workpiece; step (b) includes detecting whether a conductive path is established between the portion of wire and the bonding location of the workpiece; step (b) includes detecting when the conductive path is established by detecting at least one of (a) a predetermined current flow in the conductive path, (b) a predetermined change in capacitance between the conductive path and a ground connection of the wire bonding system, and (c) a predetermined phase shift of current flowing in the conductive path; step (b) includes determining whether a detection signal exceeds a threshold during at least a portion of the wire bonding process; and further comprising a step of determining a clamping status of a clamping system used to clamp the workpiece against a support structure of the wire bonding system using data from step (c).

### BRIEF DESCRIPTION OF THE DRAWINGS

The invention is best understood from the following detailed description when read in connection with the accompanying drawings. It is emphasized that, according to common practice, the various features of the drawings are not to scale. On the contrary, the dimensions of the various features are arbitrarily expanded or reduced for clarity. Included in the drawings are the following figures:

FIGS. 1A-1B are block diagram views of a wire bonding system useful for illustrating methods of determining a bonding status between a portion of a wire and a workpiece in accordance with an exemplary embodiment of the invention;

FIG. 2 is a block diagram view of a wire bonding system useful for illustrating methods of determining another bonding status between a portion of a wire and a workpiece in accordance with an exemplary embodiment of the invention;

FIGS. 3A-3B are block diagram views of a wire bonding system useful for illustrating methods of determining additional bonding statuses between portions of a wire and a workpiece in accordance with various exemplary embodiments of the invention;

FIGS. 4A-4B are block diagram views of a wire bonding system useful for illustrating methods of determining additional bonding statuses between portions of a wire and a workpiece in accordance with various exemplary embodiments of the invention;

FIGS. 5A-5C are timing diagrams illustrating a status of detection signals during wire bonding cycles useful for determining a bonding status between a portion of a wire and a workpiece in accordance with various exemplary embodiments of the invention;

FIG. 6 is a flow diagram illustrating a method of determining a bonding status between a portion of wire and a workpiece in accordance with various exemplary embodiments of the invention; and

FIGS. 7A-7C are block diagram views of a wire bonding system useful for illustrating methods of determining a bonding status between a portion of a wire and a workpiece in accordance with yet another exemplary embodiment of the invention.

### DETAILED DESCRIPTION

According to various exemplary embodiments of the invention, a bonding status (e.g., a bonded wire condition, a broken wire condition, a missing wire condition, etc.) is detected during formation of a wire bond (e.g., during the wire bonding process, during the wire bonding cycle, etc.). Methods of detecting the bonding status within the scope of the invention may be applied to any type of wire bond (e.g., a first bond, a second bond, a ball bond, etc.) configured for inclusion in a bonded wire structure. Exemplary bonded wire structures include wire loops, conductive bumps formed using wire, vertical wire structures (e.g., wire structures bonded to one bonding location of a workpiece, where a portion of the wire structure extends above the portion of the wire structure bonded to the bonding location), among others.

To monitor the bonding status during the formation of a wire bond, one or more detection signals (e.g., BITS signals) may be detected during the formation of the wire bond. For example, if the detection signal is high throughout the formation of the wire bond, the bonding status may be declared “normal” (e.g., a bonded wire condition). In another example, if the detection signal is low throughout the formation of the wire bond, the bonding status may be declared “missing” (e.g., a missing wire condition). In yet another example, if the detection signal changes from high to low during the formation of the wire bond, the bonding status may be declared “broken” (e.g., a broken wire condition). Additional bonding conditions are contemplated beyond a bonded wire condition, a missing wire condition, and a broken wire condition.

In accordance with further exemplary embodiments of the invention, the detection signal(s) may be used to determine a clamping status of a clamping system used for clamping the workpiece against a support structure of the wire bonding system. For example, while monitoring the bonding status during wire bond formation, the z-axis position may be monitored (e.g., using a z-axis encoder of the wire bonding system). Unexpected z-axis variation during wire bond formation (e.g., z-axis dither) may be an indication that the clamping is unacceptable.

By monitoring the bonding status of the portion of wire during formation of a wire bond (e.g., using BITS), a more robust wire bonding process is provided. For example, in certain situations a workpiece may not be properly held down against a support structure of the wire bonding system (e.g., the workpiece may not be properly held against a heat block using vacuum). In such a situation, a conventional BITS process may not detect a problematic wire bond because there may be no adequate electrical path to the grounded heat block (i.e., a support structure).

Because aspects of the invention detect the bonding status of a portion of wire during formation of a wire bond, a wire bonding tool (e.g., a capillary) is applying a downward force, thereby pushing the workpiece against the support structure (e.g., the heat block) to make a good electrical connection. By detecting poor wire bonding conditions, automatic recovery features may be utilized to keep a wire bonding system in operation. Further, wire bonding efficiency (e.g., UPH, also known as “units per hour”) and device yield may be increased by enabling the detection of the bonding status of a portion of wire during formation of a wire bond.

In accordance with exemplary aspects of the invention, as the bonding status of a portion of wire is monitored (and/or detected) during formation of a wire bond, ultrasonic energy may be applied during the monitoring and/or detection. In various of the drawings, such ultrasonic energy is indicated by a double headed arrow labelled “USG”. It should be understood that the ultrasonic energy may be active during wire bond formation, and may be shut off if an abnormal condition is detected (e.g., a missing wire, a broken wire, etc.).

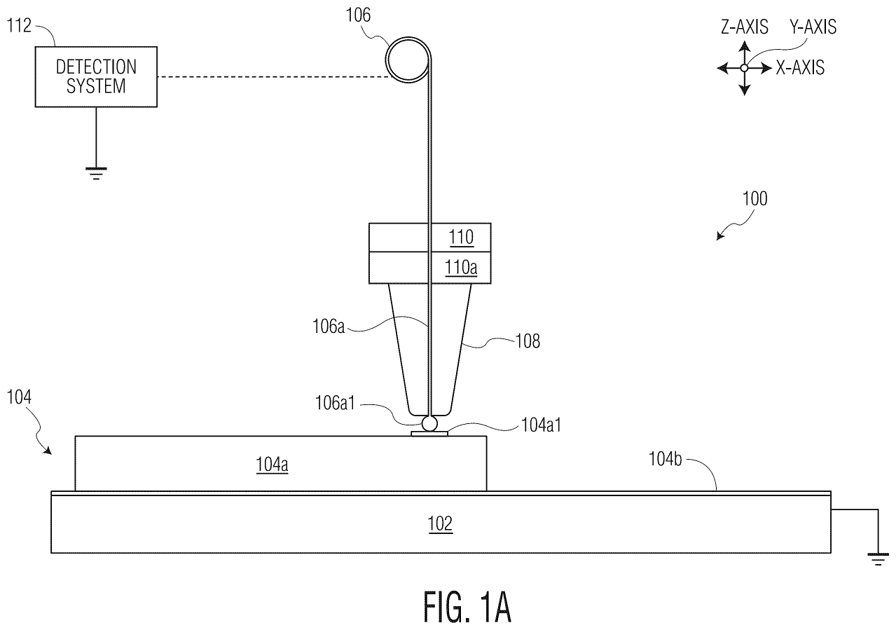

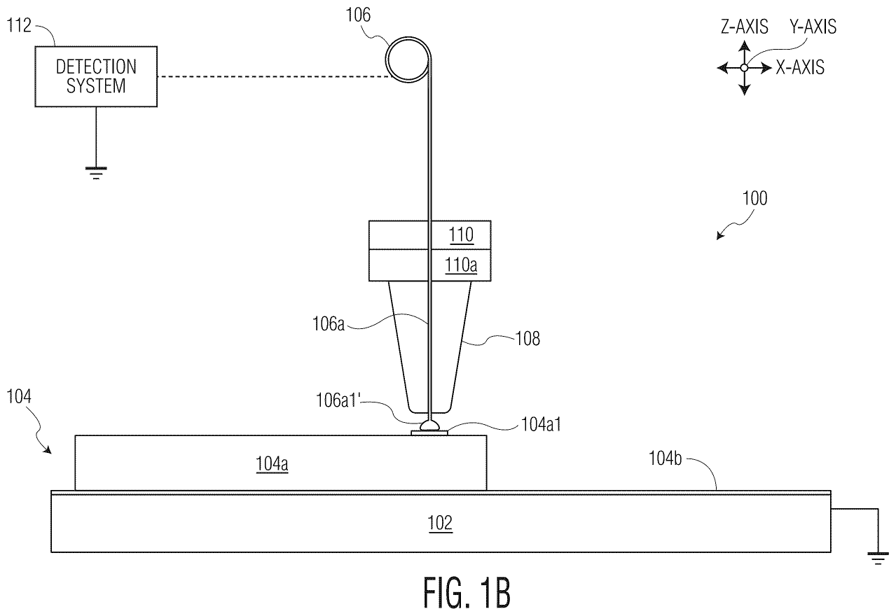

Referring now to FIG. 1A, a wire bonding system 100 is provided. Wire bonding system 100 includes a support structure 102 (e.g., a heat block, an anvil, etc.) for supporting a workpiece 104. In FIG. 1A, the exemplary workpiece 104 includes a substrate 104b (e.g., a leadframe), and a semiconductor die 104a attached to substrate 104b. Semiconductor die 104a includes a bonding location 104a1 (e.g., a die pad, a conductive trace, etc.).

Wire bonding system 100 also includes a wire source 106 (e.g., a wire spool) providing wire 106a. Wire bonding system 100 also includes a wire bonding tool 108 (e.g., a capillary wire bonding tool) coupled to an ultrasonic transducer 110a. Ultrasonic transducer 110a is carried by (and may be considered part of) a bond head assembly 110 of wire bonding system 100. Wire bonding system 100 also includes a detection system 112 for detecting a bonding status of a portion of wire 106a. Other elements of wire bonding system 100, such as one or more sets of wire clamps, are omitted for simplicity.

As shown in FIG. 1A, a length of wire 106a extends through wire bonding tool 108. A free air ball 106a1 (i.e., a portion of wire 106a) has been formed on an end of wire 106a, and is seated at the tip of wire bonding tool 108. Free air ball 106a1 has been brought into contact with bonding location 104a1 of semiconductor die 104a. FIG. 1A illustrates the start of the formation of a wire bond, whereby free air ball 106a1 is being ultrasonically bonded to bonding location 104a1. The wire bond formation is complete in FIG. 1B, as free air ball 106a1 is now labelled as bonded free air ball 106a1′. Bonded free air ball 106a1′ may be configured to be part of a number of different types of wire structures (e.g., part of a wire loop, part (and possibly all) of a conductive bump, part of a vertical wire structure, etc.).

During the wire bond formation process shown in FIGS. 1A-1B (where ultrasonic energy from transducer 110a is used to ultrasonically bond free air ball 106a1 to bonding location 104a1), detection system 112 is used to monitor the bonding status between free air ball 106a1 and bonding location 104a1. For example, detection system 112 may detect contact (e.g., electrical continuity) between free air ball 106a1 and bonding location 104a1 (e.g., detecting contact between a portion of wire and the bonding location). Stated another way, detection system 112 may detect whether a conductive path is established between free air ball 106a1 and bonding location 104a1. In order to detect whether such a conductive path is established, detection system 112 may detect, for example, at least one of (a) a predetermined current flow in the conductive path, (b) a predetermined change in capacitance between the conductive path and a ground connection of the wire bonding system, and (c) a predetermined phase shift of current flowing in the conductive path. Such an conductive path may be detected (and the bonding status monitored) by detecting contact between (i) a wire source including the portion of wire and (ii) the bonding location.

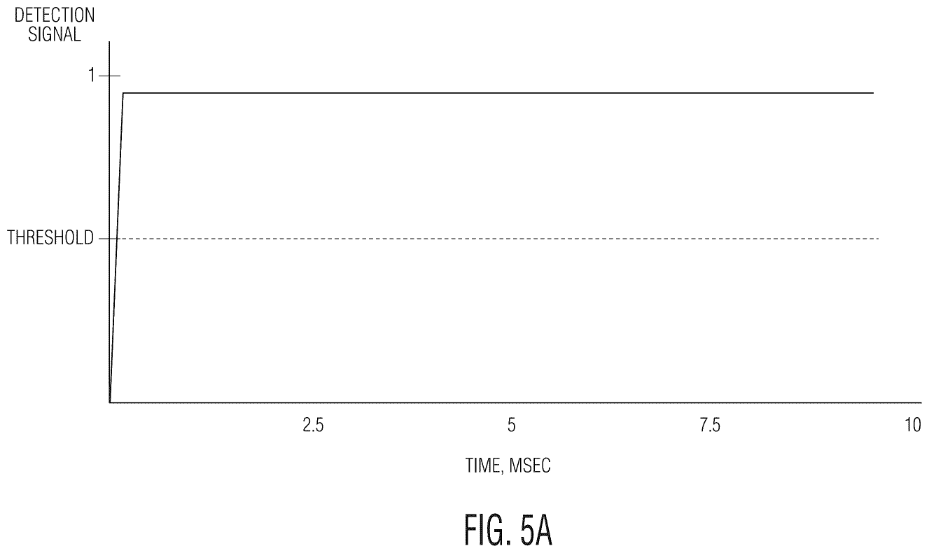

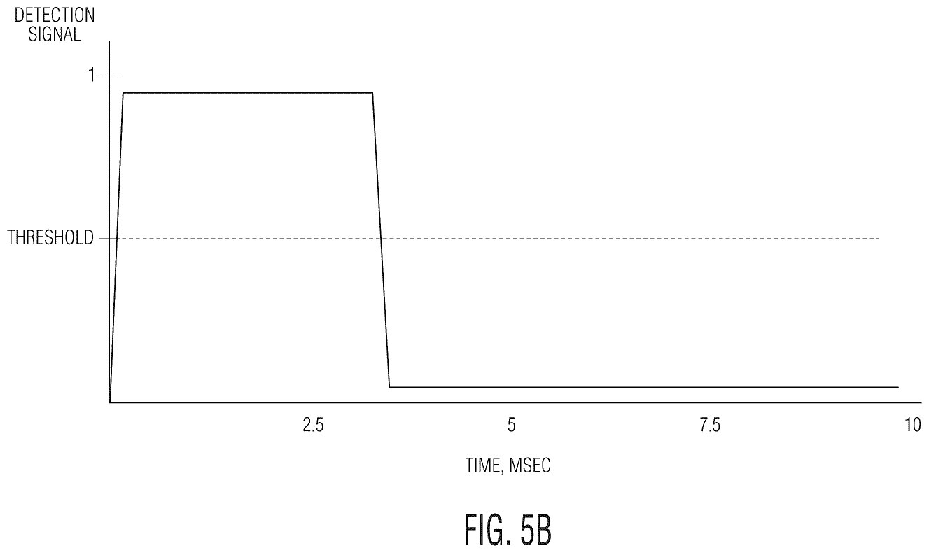

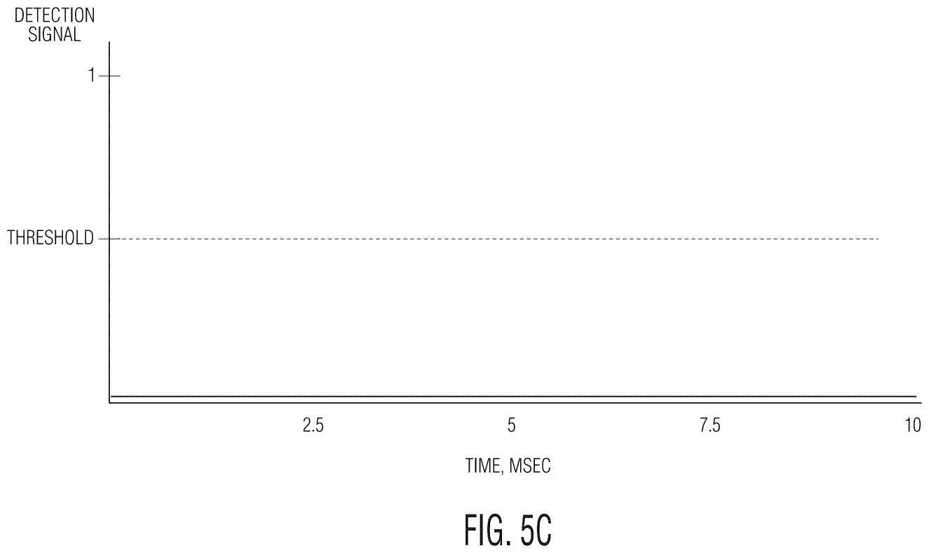

Thus, detection system 112 analyzes one or more detection signals (e.g., electrical current, capacitance, etc.) in order to monitor the bonding status between free air ball 106a1 and bonding location 104a1. FIG. 5A is a timing diagram of a wire bonding process (during the bonding cycle of a wire bond formation). The x-axis of the timing diagram illustrates an exemplary time for forming a wire bond (e.g., 10 milliseconds). The y-axis of the timing diagram illustrates the detection signal analyzed by the detection system. A “threshold” value of the detection signal is also shown—where the threshold value is intended to be a value of the detection signal above which the bonding process may be considered acceptable. As shown in FIG. 5A, the detection signal is high (e.g., above the threshold) throughout the formation of the wire bond. Thus, the bonding status may be declared “normal” (e.g., a bonded wire condition).

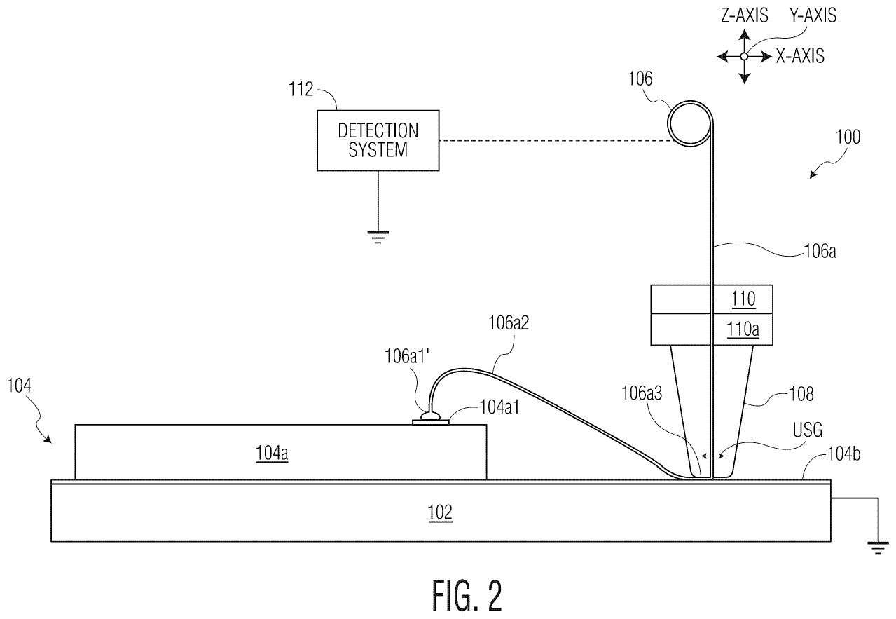

In FIG. 2, after formation of a bonded free air ball 106a1′ (e.g., a first bond of a wire loop), a length of wire is extended toward a second bond location on substrate 104b. During formation of a second bond 106a3 of a wire loop 106a2, the bonding status may be declared “normal” (e.g., a bonded wire condition), because the detection signal may be high (e.g., above the threshold) throughout the formation of the wire bond (as in FIG. 5A).

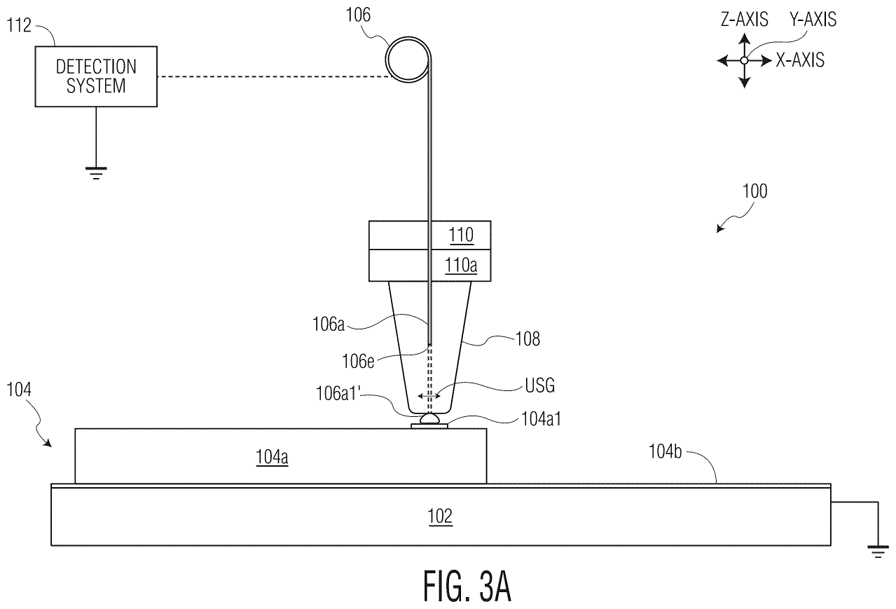

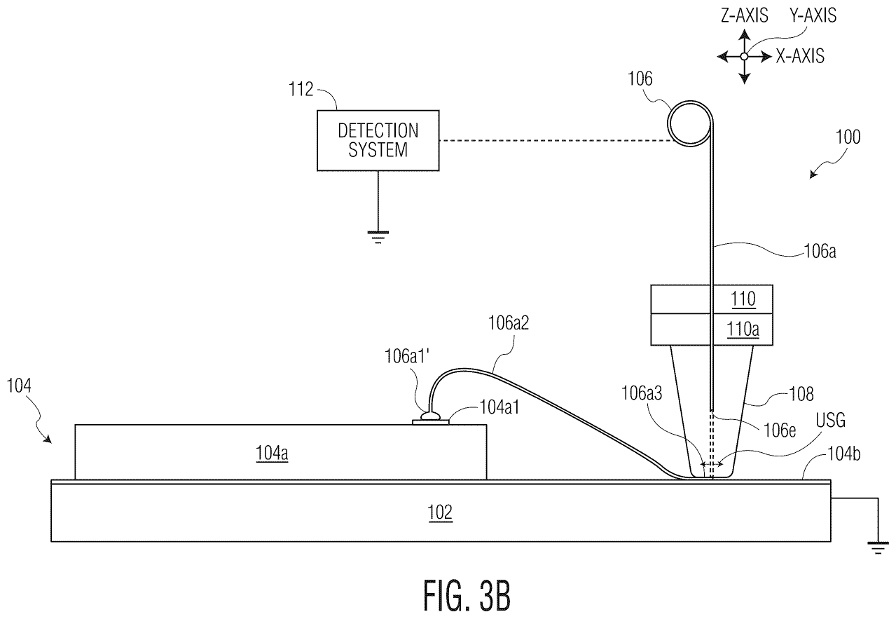

FIG. 3A illustrates formation of bonded free air ball 106a1′, similar to that shown in FIGS. 1A-1B. However, in FIG. 3A, wire 106a is broken with respect to bonded free air ball 106a1′. In this situation, the detection signal may not return a “normal” condition because the electrical path through support structure 102 may not be adequate. For example, referring specifically to FIG. 5B, the detection signal begins high (e.g., above the threshold), but then changes from high to low. In such a case, the bonding status may be declared “broken” (e.g., a broken wire condition).

In the example of FIG. 3B, after formation of bonded free air ball 106a1′ (i.e., a first bond of a wire loop), a length of wire is extended toward a second bond location on substrate 104b (similar to the process of FIG. 2). During formation of second bond 106a3 of wire loop 106a2, wire 106a is broken with respect to second bond 106a3. In this situation, the detection signal may not return a “normal” condition because the electrical path through support structure 102 may not be adequate. For example, referring specifically to FIG. 5B, the detection signal begins high (e.g., above the threshold), but then changes from high to low. In such a case, the bonding status may be declared “broken” (e.g., a broken wire condition).

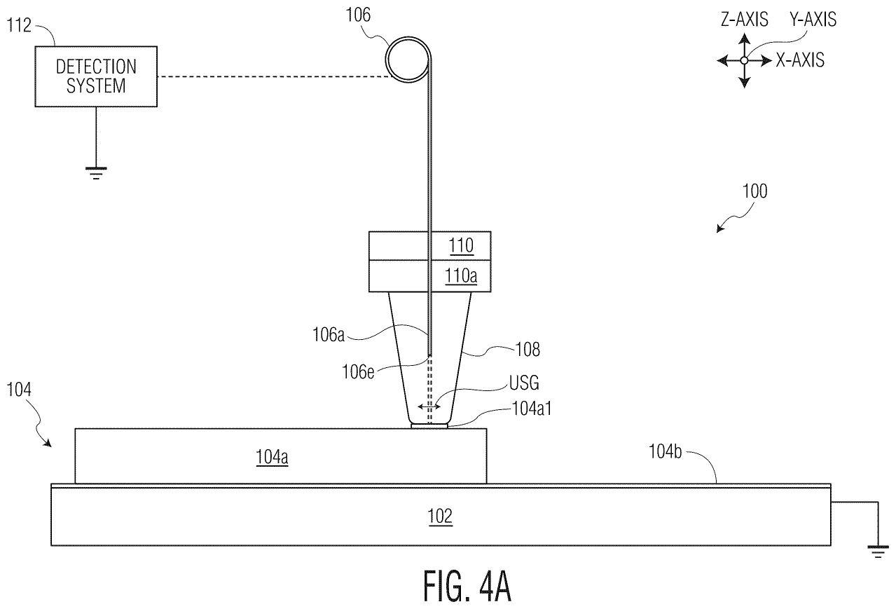

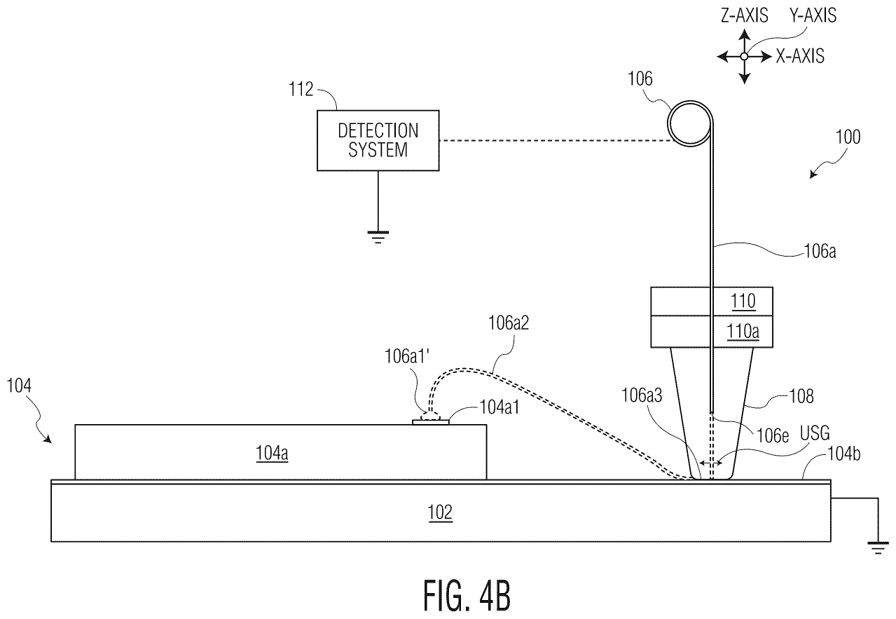

FIG. 4A illustrates attempted formation of a bonded portion of wire (e.g., such as formation of bonded free air ball 106a1′, similar to that shown in FIGS. 1A-1B). However, in FIG. 4A, there is no portion of wire 106a at the tip of wire bonding tool 108 to be bonded to bonding location 104a1 (e.g., the wire is missing). In this situation, the detection signal may not return a “normal” condition because the electrical path through the support structure may not be adequate. For example, referring specifically to FIG. 5C, the detection signal is low throughout the formation of the wire bond. In such a case, the bonding status may be declared “missing” (e.g., a missing wire condition).

In the example of FIG. 4B, after formation of bonded free air ball 106a1′ (i.e., a first bond of a wire loop), a length of wire is extended toward a second bond location on substrate 104b (similar to the process of FIG. 2). During attempted formation of a second bond of a wire loop, there is no portion of wire 106a at the tip of wire bonding tool 108 to be bonded to a bonding location of substrate 104b (e.g., the wire is missing). In this situation, the detection signal may not return a “normal” condition because the electrical path through the support structure may not be adequate. For example, referring specifically to FIG. 5C, the detection signal is low throughout the formation of the wire bond. In such a case, the bonding status may be declared “missing” (e.g., a missing wire condition). In FIG. 4B, wire loop 106a2 is shown in dotted lines to make clear that the wire loop may, or may not, have been formed prior to the formation (or attempted formation) of second bond 106a3. That is, the wire is missing—but could be missing at any location along, or adjacent, wire loop 106a2.

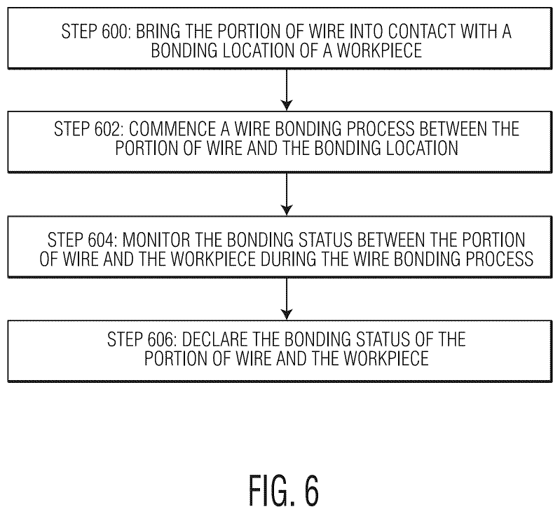

FIG. 6 is a flow diagram illustrating a method of determining a bonding status between a portion of wire and a workpiece. At Step 600, the portion of wire is brought into contact with a bonding location of the workpiece (e.g., see FIG. 1A, FIG. 2, FIG. 3A, FIG. 3B, etc.). At Step 602, a wire bonding process (e.g., a first bond process, a ball bond process, a second bond process, a stitch bond process, etc.) is commenced between the portion of wire and the bonding location. At Step 604, the bonding status between the portion of wire and the bonding location is monitored (e.g., using detection system 112). At Step 606, the bonding status (e.g., a bonded wire condition, a broken wire condition, a missing wire condition, etc.) between the portion of wire and the bonding location is declared.

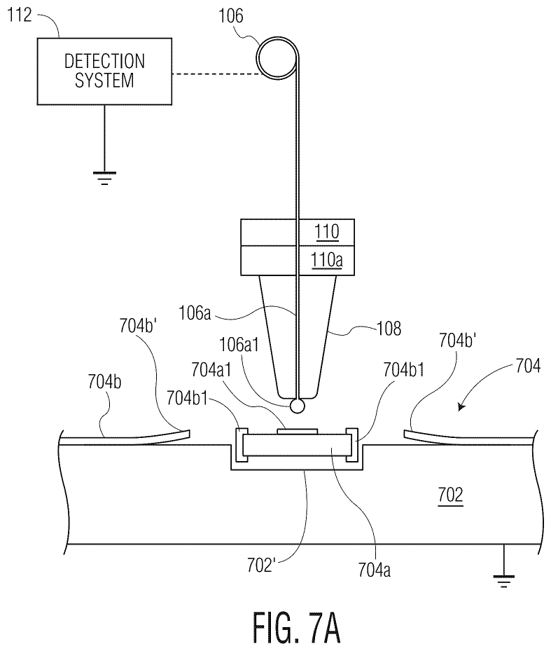

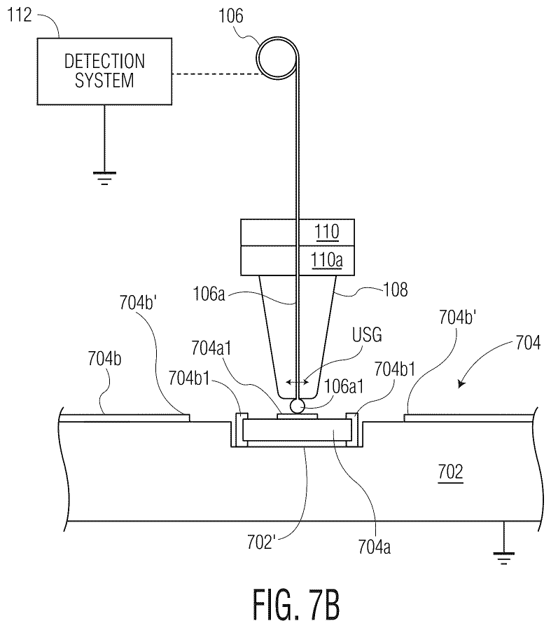

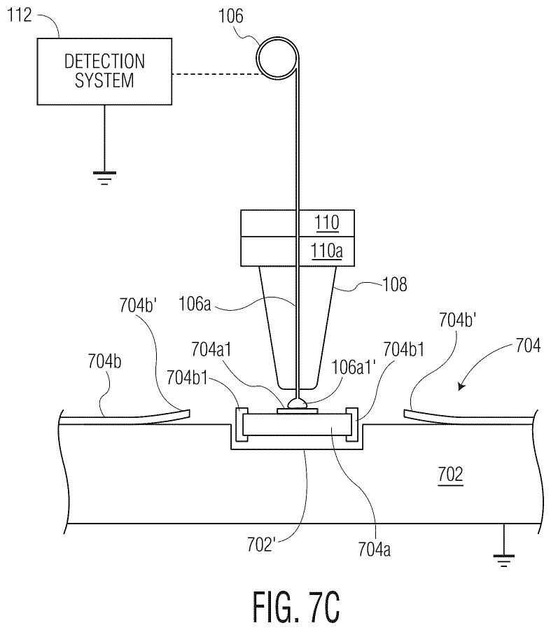

At FIG. 7A, a specific application for wire bonding is illustrated. For example, a workpiece 704 is illustrated. Workpiece 704 includes a die 704a (e.g., an LED die) on a substrate 704b (e.g., a leadframe). Lead portions 704b1 of substrate 704b are illustrated with respect to die 704a (although not clearly shown in FIGS. 7A-7C, lead portions 704b1 are part of substrate 704b). A bonding location 704a1 is shown on die 704a. A support structure 702 defines an aperture 702′ configured to receive die 704a (and lead portions 704b1). As shown in FIG. 7A, portions 704b′ of substrate 704b (and lead portions 704b1) are floating above support structure 702. In FIG. 7B, during formation of a bonded free air ball 106a1′ (using free air ball 106a1), bond force has been used to press portions 704b′ of substrate 704b (and lead portions 704b1) against support structure 702. In FIG. 7C, after bonded free air ball 106a1′ has been bonded to bonding location 104a1, wire bonding tool 108 has been raised above bonded free air ball 106a1′- and portions 704b′ of substrate 704b (and lead portions 704b1) are now again floating above support structure 702.

In an application such as shown in FIGS. 7A-7C, a detection system (such as BITS) may not be able to detect proper bonding of a bonded portion of wire (such as bonded free air ball 106a1′) if the detection occurs after bond formation in FIG. 7C (e.g., because of the floating of portions 704b′ of substrate 704b). In contrast, in accordance with exemplary embodiments of the invention, since the bonding status is monitored during formation of a wire bond (e.g., as shown in FIG. 7B), proper detection of the bonding status may be accomplished.

Using the various methods of the invention, real-time feedback regarding the bonding status of a portion of wire may be provided to the wire bonding system. Using this feedback, adjustments may be made. In one example, bonding parameters (e.g., bond force, bond time, ultrasonic energy, z-position, etc.) used during the wire bond formation may be adjusted. In a specific example, the bond force applied during bonding may be increased to avoid a floating condition (such as shown in FIG. 7A).

Further, the detection system may determine that the clamping status of a clamping system (e.g., a window clamp, a device clamp, a clamp insert, etc.) may be inadequate. In such a case, the clamping may be adjusted (e.g., the clamping force applied using clamp arms of the clamping system may be adjusted), or the clamping system may be exchanged.

In yet another example, the monitoring of the bonding status may be repeated for a plurality of wire bonds to determine if an abnormal condition (e.g., a missing or broken wire condition) occurs repeatedly, or if a single abnormal condition was an anomaly.

Although the invention is illustrated and described herein with reference to specific embodiments, the invention is not intended to be limited to the details shown. Rather, various modifications may be made in the details within the scope and range of equivalents of the claims and without departing from the invention.

What is claimed:

1. A method of determining a bonding status between a portion of wire and a workpiece on a wire bonding system, the method comprising the steps of:
(a) bringing the portion of wire into contact with a bonding location of a workpiece;
(b) commencing a wire bonding process between the portion of wire and the bonding location; and
(c) monitoring the bonding status between the portion of wire and the workpiece during the wire bonding process.

2. The method of claim 1 wherein the bonding status is monitored during step (c) by detecting contact between the portion of wire and the bonding location.

3. The method of claim 1 wherein the bonding status is monitored during step (c) by detecting contact between (i) a wire source including the portion of wire and (ii) the bonding location.

4. The method of claim 1 wherein the bonding status includes at least one of (i) a bonded wire condition, (ii) a broken wire condition, and (iii) a missing wire condition.

5. The method of claim 1 wherein the portion of wire is a free air ball configured to be bonded to the bonding location.

6. The method of claim 1 wherein the portion of wire is configured to be a first wire bond of a wire loop.

7. The method of claim 1 wherein the portion of wire is configured to be a second wire bond of a wire loop.

8. The method of claim 1 wherein the portion of wire is configured to be a conductive bump.

9. The method of claim 1 wherein the portion of wire is configured to be a vertical wire structure bonded to the workpiece at a single location.

10. The method of claim 1 further comprising the step of (d) declaring the bonding status of the portion of wire and the workpiece.

11. The method of claim 1 wherein step (c) includes detecting whether a conductive path is established between the portion of wire and the bonding location of the workpiece.

12. The method of claim 11 wherein step (c) includes detecting when the conductive path is established by detecting at least one of (a) a predetermined current flow in the conductive path, (b) a predetermined change in capacitance between the conductive path and a ground connection of the wire bonding system, and (c) a predetermined phase shift of current flowing in the conductive path.

13. The method of claim 1 wherein step (b) includes determining whether a detection signal exceeds a threshold during at least a portion of the wire bonding process.

14. The method of claim 1 further comprising a step of determining a clamping status of a clamping system used to clamp the workpiece against a support structure of the wire bonding system using data from step (c).

15. A method of determining a clamping status of a clamping system used for clamping a workpiece against a support structure on a wire bonding system, the method comprising the steps of:
(a) bringing a portion of wire into contact with a bonding location of the workpiece;
(b) commencing a wire bonding process between the portion of wire and the bonding location;
(c) monitoring a bonding status between the portion of wire and the workpiece during the wire bonding process; and
(d) determining the clamping status of the clamping system using the bonding status data monitored in step (c).

16. The method of claim 15 wherein the bonding status is monitored during step (c) by detecting contact between the portion of wire and the bonding location.

17. The method of claim 15 wherein the bonding status is monitored during step (c) by detecting contact between (i) a wire source including the portion of wire and (ii) the bonding location.

18. The method of claim 15 wherein the bonding status includes at least one of (i) a bonded wire condition, (ii) a broken wire condition, and (iii) a missing wire condition.

19. The method of claim 15 further comprising the step of declaring the bonding status of the portion of wire and the workpiece.

20. The method of claim 15 wherein step (c) includes detecting whether a conductive path is established between the portion of wire and the bonding location of the workpiece.
